(19) United States
(12) Patent Application Publication
(10) Pub. No.: US 2025/0246353 A1
(43) Pub. Date: Jul. 31, 2025

(54) RuAl and MgTiO Lamination For Effective Buffer and Interlayers For Topological Material Layers

(71) Applicant: Western Digital Technologies, Inc., San Jose, CA (US)

(72) Inventors: Quang LE, San Jose, CA (US); Brian R. YORK, San Jose, CA (US); Michael A. GRIBELYUK, Stamford, CT (US); Xiaoyong LIU, San Jose, CA (US); Son T. LE, San Jose, CA (US); Maki MAEDA, Fujisawa-shi (JP); Hisashi TAKANO, Fujisawa-shi (JP)

(73) Assignee: Western Digital Technologies, Inc., San Jose, CA (US)

(21) Appl. No.: 19/040,639

(22) Filed: Jan. 29, 2025

Related U.S. Application Data
(60) Provisional application No. 63/627,465, filed on Jan. 31, 2024.

(51) Int. Cl. H01F 10/32; G11B 5/39; H10B 61/00

(52) U.S. Cl. CPC H01F 10/329; G11B 5/39; H10B 61/20

(57) ABSTRACT

The present disclosure generally relates to topological insulator (TI) or a topological semi-metal (TSM) based spin-orbit torque (SOT) devices. The SOT device comprises a buffer layer, a TI or TSM layer, an interlayer, and a ferromagnetic layer. The buffer layer comprising a texture layer structure, where the texture layer structure comprises one or more of: (1) two or more laminated layers of RuAl and MgTiO or MgO, (2) laminations of MgO and W, (3) W-X body-centered cubic (bcc) alloys, where X is one or more of Ta, Hf, Ti, V, Nb, and Mo, or (4) combinations thereof. The texture layer structure has a (100) orientation. The TI or TSM layer comprises BiSb having a (012) orientation or YPtBi having a (100) orientation. The buffer layer may further comprise one or more body-centered cubic layers and an oxide layer.

### CROSS-REFERENCE TO RELATED APPLICATIONS

This application claims benefit of U.S. provisional patent application Ser. No. 63/627,465, filed Jan. 31, 2024, which is herein incorporated by reference.

### BACKGROUND OF THE DISCLOSURE

### Field of the Disclosure

Embodiments of the present disclosure generally relate to spin-orbit torque (SOT) device comprising a topological insulator (TI) layer.

### Description of the Related Art

BiSb layers are narrow band gap topological insulators with both giant spin Hall effect and high electrical conductivity. BiSb is a material that has been proposed in various spin-orbit torque (SOT) device applications, such as for a spin Hall layer for magnetoresistive random access memory (MRAM) devices, magnetic recording read heads, sensors, and energy-assisted magnetic recording (EAMR) write heads.

However, utilizing BiSb materials in commercial SOT applications can present several obstacles. For example, BiSb materials have low melting points, large grain sizes, significant Sb migration issues upon thermal annealing due to its film roughness, difficulty maintaining a desired (012) or (001) orientation for maximum spin Hall effect, and are generally soft and easily damaged by ion milling. Furthermore, the buffer layers needed to grow the BiSb layer are often required to be deposited at high temperatures, such as about 300° C. or higher with physical vapor deposition (PVD), in order for the BiSb layer to grow in the desired orientation.

Therefore, there is a need for an improved SOT device utilizing a topological insulator (TI) layer having a desired crystal orientation.

### SUMMARY OF THE DISCLOSURE

The present disclosure generally relates to topological insulator (TI) or a topological semi-metal (TSM) based spin-orbit torque (SOT) devices. The SOT device comprises a buffer layer, a TI or TSM layer, an interlayer, and a ferromagnetic layer. The buffer layer comprising a texture layer structure, where the texture layer structure comprises one or more of: (1) two or more laminated layers of RuAl and MgTiO or MgO, (2) laminations of MgO and W, (3) W-X body-centered cubic (bcc) alloys, where X is one or more of Ta, Hf, Ti, V, Nb, and Mo, or (4) combinations thereof. The texture layer structure has a (100) orientation. The TI or TSM layer comprises BiSb having a (012) orientation or YPtBi having a (100) orientation. The buffer layer may further comprise one or more body-centered cubic layers and an oxide layer.

In one embodiment, a spin-orbit torque (SOT) device comprises a texture layer structure having a (100) orientation comprising one or more of: (1) two or more laminated layers of RuAl and MgTiO or MgO, (2) laminations of MgO and W, or (3) W-X body-centered cubic (bcc) alloys, where X is one or more of Ta, Hf, Ti, V, Nb, and Mo, the texture layer structure having a (100) orientation, and a topological insulator (TI) or a topological semi-metal (TSM) layer disposed over the texture layer structure.

In another embodiment, a spin-orbit torque (SOT) device comprises a seed layer comprising an amorphous material, a texture layer structure disposed on the seed layer, the texture layer structure having a (100) orientation comprising one or more of: (1) two or more laminated layers of RuAl and MgTiO or MgO, (2) laminations of MgO and W, or (3) W-X body-centered cubic (bcc) alloys, where X is one or more of Ta, Hf, Ti, V, Nb, and Mo, wherein the RuAl of each laminated layer has a greater thickness than the MgTiO or MgO of each laminated layer, a topological insulator (TI) or a topological semi-metal (TSM) layer disposed over the texture layer structure, an interlayer disposed on the TI or TSM layer, and a ferromagnetic layer disposed on the interlayer.

In yet another embodiment, a spin-orbit torque (SOT) device comprises a buffer layer comprising: a texture layer disposed on a seed layer, the texture layer structure having a (100) orientation comprising one or more of: (1) two or more laminated layers of RuAl and MgTiO or MgO, (2) laminations of MgO and W, or (3) W-X body-centered cubic (bcc) alloys, where X is one or more of Ta, Hf, Ti, V, Nb, and Mo, a first barrier layer disposed on the texture layer structure, and an oxide layer disposed on the first barrier layer, a topological insulator (TI) or a topological semi-metal (TSM) layer disposed over the texture layer structure, an interlayer disposed on the TI or TSM layer, and a ferromagnetic layer disposed on the interlayer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic illustration of certain embodiments of a magnetic media drive including a magnetic recording head having a SOT MTJ device.

FIG. 2 is a fragmented, cross-sectional side view of certain embodiments of a read/write head having a SOT MTJ device.

FIGS. 3A-3B illustrate spin orbit torque (SOT) devices, according to various embodiments.

FIGS. 4A-4C illustrate various graphs showing examples of showing examples of buffer layers comprising laminated texture stacks of RuAl and MgTiO or MgO, according to various embodiments.

FIG. 5A is a schematic cross-sectional view of a SOT device for use in a MAMR magnetic recording head, such as the MAMR magnetic recording head of the drive of FIG. 1 or other suitable magnetic media drives.

FIGS. 5B-5C are schematic MFS views of certain embodiments of a portion of a MAMR magnetic recording head with a SOT device of FIG. 5A.

FIG. 6 is a schematic cross-sectional view of an MRAM device according to one embodiment, which has a top SOT stack configuration.

FIG. 7 is a schematic cross-sectional view of another MRAM device according to one embodiment, which has a bottom SOT stack configuration, with a TI or TSM bottom layer below the MTJ, in contrast to the top SOT stack configuration of FIG. 6.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to topological insulator (TI) or a topological semi-metal (TSM) based spin-orbit torque (SOT) devices. The SOT device comprises a buffer layer, a TI or TSM layer, an interlayer, and a ferromagnetic layer. The buffer layer comprising a texture layer structure, where the texture layer structure comprises one or more of: (1) two or more laminated layers of RuAl and MgTiO or MgO, (2) laminations of MgO and W, (3) W-X body-centered cubic (bcc) alloys, where X is one or more of Ta, Hf, Ti, V, Nb, and Mo, or (4) combinations thereof. The texture layer structure has a (100) orientation. The TI or TSM layer comprises BiSb having a (012) orientation or YPtBi having a (100) orientation. The buffer layer may further comprise one or more body-centered cubic layers and an oxide layer.

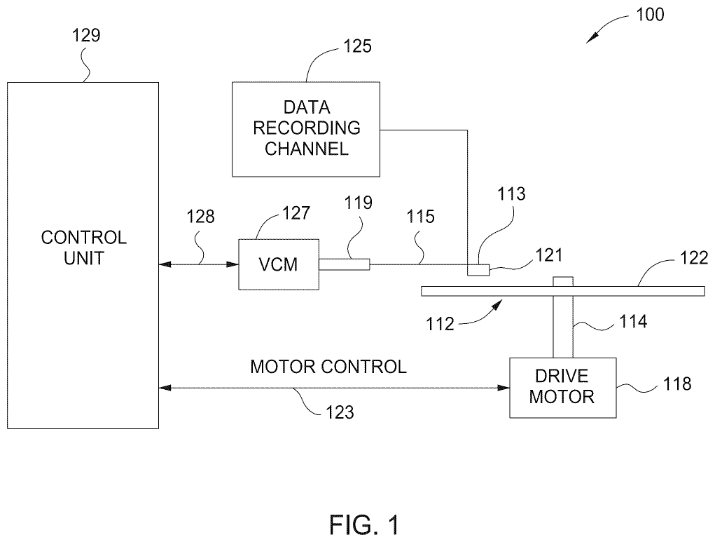

FIG. 1 is a schematic illustration of certain embodiments of a magnetic media drive 100 including a magnetic recording head having a SOT MTJ device. Such a magnetic media drive may be a single drive or comprise multiple drives. For the sake of illustration, a single disk drive 100 is shown according to certain embodiments. As shown, at least one rotatable magnetic disk 112 is supported on a spindle 114 and rotated by a drive motor 118. The magnetic recording on each magnetic disk 112 is in the form of any suitable patterns of data tracks, such as annular patterns of concentric data tracks (not shown) on the magnetic disk 112.

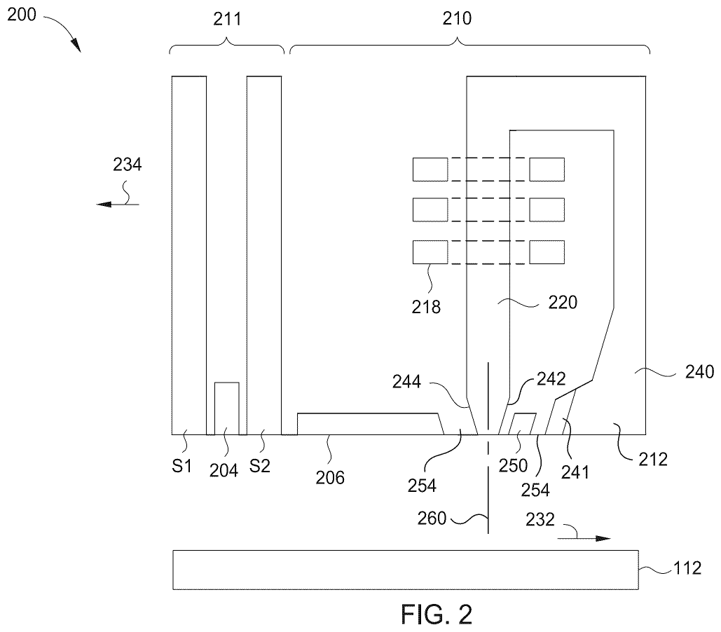

At least one slider 113 is positioned near the magnetic disk 112, each slider 113 supporting one or more magnetic head assemblies 121 that include a SOT device. As the magnetic disk 112 rotates, the slider 113 moves radially in and out over the disk surface 122 so that the magnetic head assembly 121 may access different tracks of the magnetic disk 112 where desired data are written. Each slider 113 is attached to an actuator arm 119 by way of a suspension 115. The suspension 115 provides a slight spring force which biases the slider 113 toward the disk surface 122. Each actuator arm 119 is attached to an actuator means 127. The actuator means 127 as shown in FIG. 2 may be a voice coil motor (VCM). The VCM includes a coil movable within a fixed magnetic field, the direction and speed of the coil movements being controlled by the motor current signals supplied by control unit 129.

During operation of the disk drive 100, the rotation of the magnetic disk 112 generates an air bearing between the slider 113 and the disk surface 122 which exerts an upward force or lift on the slider 113. The air bearing thus counter-balances the slight spring force of suspension 115 and supports slider 113 off and slightly above the disk surface 122 by a small, substantially constant spacing during normal operation.

The various components of the disk drive 100 are controlled in operation by control signals generated by control unit 129, such as access control signals and internal clock signals. Typically, the control unit 129 comprises logic control circuits, storage means and a microprocessor. The control unit 129 generates control signals to control various system operations such as drive motor control signals on line 123 and head position and seek control signals on line 128. The control signals on line 128 provide the desired current profiles to optimally move and position slider 113 to the desired data track on disk 112. Write and read signals are communicated to and from write and read heads on the assembly 121 by way of recording channel 125.

The above description of a typical magnetic media drive and the accompanying illustration of FIG. 1 are for representation purposes only. It should be apparent that magnetic media drives may contain a large number of media, or disks, and actuators, and each actuator may support a number of sliders.

FIG. 2 is a fragmented, cross-sectional side view of certain embodiments of a read/write head 200 having a SOT device. The read/write head 200 faces a magnetic media 112. The read/write head 200 may correspond to the magnetic head assembly 121 described in FIG. 1. The read/write head 200 includes a media facing surface (MFS) 212, such as a gas bearing surface, facing the disk 112, a write head 210, and a magnetic read head 211. As shown in FIG. 2, the magnetic media 112 moves past the write head 210 in the direction indicated by the arrow 232 and the read/write head 200 moves in the direction indicated by the arrow 234.

In some embodiments, the magnetic read head 211 is a magnetoresistive (MR) read head that includes an MR sensing element 204 located between MR shields S1 and S2. In other embodiments, the magnetic read head 211 is a magnetic tunnel junction (MTJ) read head that includes a MTJ sensing device 204 located between MR shields S1 and S2. The magnetic fields of the adjacent magnetized regions in the magnetic disk 112 are detectable by the MR (or MTJ) sensing element 204 as the recorded bits. The SOT device of various embodiments can be incorporated into the read head 211 as the sensing element. An example of an SOT read head is described in co-pending patent application titled “Topological Insulator Based Spin Torque Oscillator Reader,” U.S. application Ser. No. 17/828,226, filed May 31, 2022, assigned to the same assignee of this application, which is herein incorporated by reference. Another example of an SOT read head is described in co-pending patent applications titled “Non-Localized Spin Valve Reader Hybridized With Spin Orbit Torque Layer,” U.S. application Ser. No. 18/367,877, filed Sep. 13, 2023, and “Non-Localized Spin Valve Multi-Free-Layer Reader Hybridized With Spin Orbit Torque Layers,” U.S. application Ser. No. 18/367,882, filed Sep. 13, 2023, both of which are herein incorporated by reference.

The write head 210 includes a main pole 220, a leading shield 206, a trailing shield 240, an optional spin orbital torque (SOT) device 250, and a coil 218 that excites the main pole 220. The coil 218 may have a “pancake” structure which winds around a back-contact between the main pole 220 and the trailing shield 240, instead of a “helical” structure shown in FIG. 2. When included, e.g., to achieve a Microwave Assisted Magnetic Recording (MAMR) effect, the SOT device 250 is formed in a gap 254 between the main pole 220 and the trailing shield 240. The main pole 220 includes a trailing taper 242 and a leading taper 244. The trailing taper 242 extends from a location recessed from the MFS 212 to the MFS 212. The leading taper 244 extends from a location recessed from the MFS 212 to the MFS 212. The trailing taper 242 and the leading taper 244 may have the same degree of taper, and the degree of taper is measured with respect to a longitudinal axis 260 of the main pole 220. In some embodiments, the main pole 220 does not include the trailing taper 242 and the leading taper 244. Instead, the main pole 220 includes a trailing side (not shown) and a leading side (not shown), and the trailing side and the leading side are substantially parallel. The main pole 220 may be a magnetic material, such as a FeCo alloy. The leading shield 206 and the trailing shield 240 may be a magnetic material, such as a NiFe alloy. In certain embodiments, the trailing shield 240 can include a trailing shield hot seed layer 241. The trailing shield hot seed layer 241 can include a high moment sputter material, such as CoFeN, FeXN, or FeX, where X includes at least one of N, AI, Ni, Co, Ta, Re, Ir, Pt, Rh, Ta, Zr, and Ti. In certain embodiments, the trailing shield 240 does not include a trailing shield hot seed layer. In other embodiments, instead of an SOT device 250 it may be a conductive stack in the write gap. In certain embodiments, the read/write head 200 additionally includes mechanisms (not shown) for supporting Heat Assisted Magnetic Recording (HAMR), which may include a waveguide coupled to a light source and a near field transducer (NFT) placed adjacent to the main pole 220 and coupled to the waveguide to convert the delivered light into a heating spot on the media.

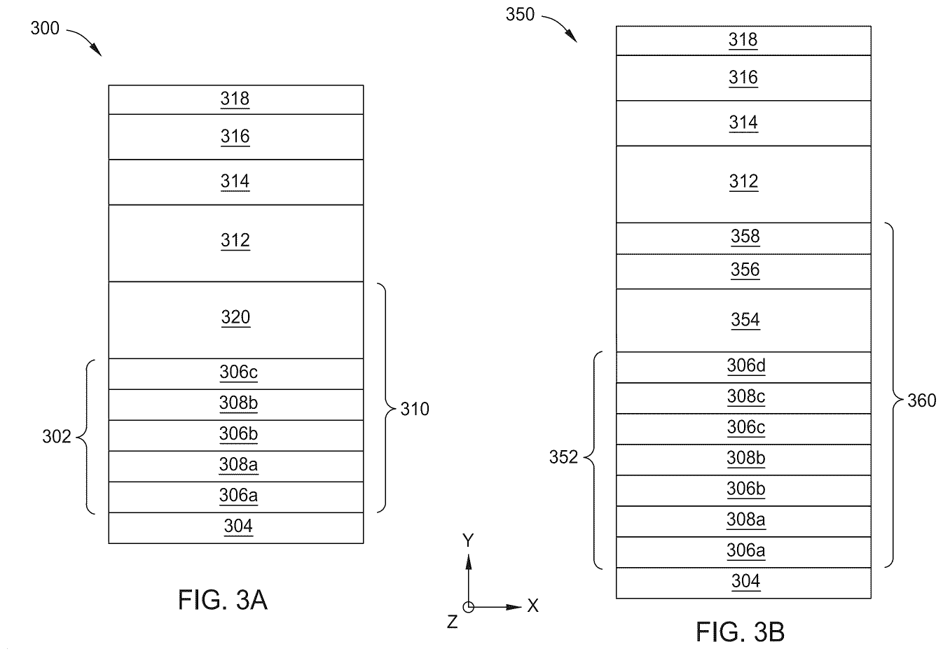

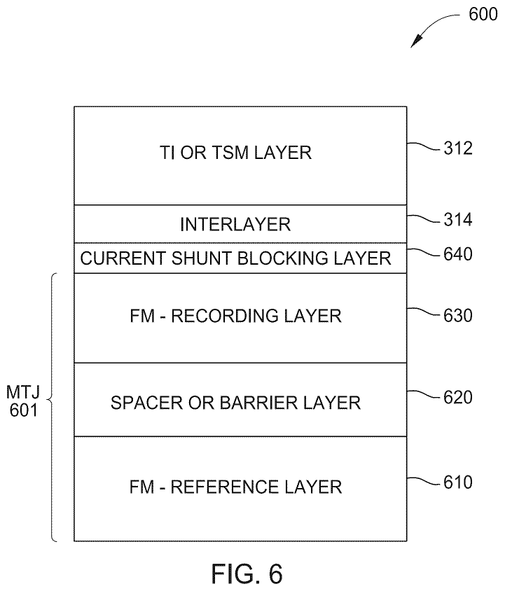

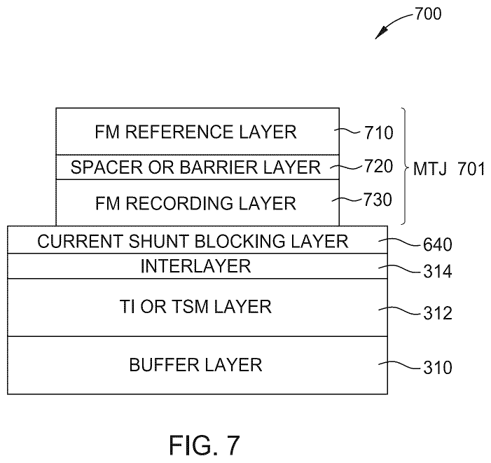

FIGS. 3A-3B illustrate spin orbit torque (SOT) devices 300, 350, respectively, according to various embodiments. The SOT devices 300, 350 may each individually be used in the recording head of the drive 100 of FIG. 1, in the reader, and/or writer portions of the head 200 of FIG. 2, or other suitable magnetic media drives. The SOT devices 300, 350 may each individually be an MTJ in sensors or used in MRAM applications, such as the example MRAM embodiments disclosed in FIGS. 6 and 7, and spin-charge conversion layers/structures in logic circuit that can be used as neuromorphic, neuron elements or other machine learning/computational elements as part of artificial intelligence chips. Other applications include magnetic sensors via a direct or indirect spin Hall effect, and spin Hall oscillators. Aspects of the SOT devices 300, 350 may be used in combination with one another.

The SOT device 300 of FIG. 3A comprises an amorphous condition layer 304, which may be referred to herein as a seed layer 304, a buffer layer 310 disposed on the seed layer 304, a topological insulator (TI) layer or a topological semi-metal (TSM) layer 312 (hereinafter referred to as a TI or TSM layer 312) disposed on the buffer layer 310, an interlayer 314 disposed on the TI or TSM layer 312, a ferromagnetic (FM) layer 316 disposed on the interlayer 314, and a cap layer 318 disposed on the FM layer 316.

The TI or TSM layer 312 comprises YPtBi having a (100) orientation or BiSb having a (012) orientation. In some embodiments, the TI or TSM layer 312 comprises doped BiSbX (where X is a dopant), such as BiSbGe, or doped YPtBiX (where X is a dopant), such as YPtBiCu. The TI or TSM layer 312 has a thickness in the y-direction of about 60 Å to about 200 Å, such as about 120 Å. The buffer layer 310 may comprise a laminated structure or texture stack comprising (1) one or more materials, such as RuAl, MgO, MgTiO, CrMo, TiO, Ru, CoAl, IrAl, in combination with (2) one or two or more laminated layers of RuAl and MgTiO or MgO or laminations of MgO, and (3) W or W-X bcc alloys where X is one or more of Ta, Hf, Ti, V, Nb, and Mo, or combinations thereof.

The buffer layer 310 comprises a laminated texture stack 302 disposed over the seed layer 304, and a barrier layer 320 disposed between the laminated texture stack 302 and the TI or TSM layer 312. The barrier layer 320 may comprise an ordered B2, disordered bcc binary or ternary alloy, or higher alloy material. The barrier layer 320 may comprise one or more of: W, Ta, Hf, W, Ir, Pt, Y, Zr, Nb, Mo, Mg, Sc, Ti, V, Cr, Fe, Co, Ni, Cu, Ru, Rh, and Ag. In some embodiments, the bcc or B2 alloys have lattice parameters in the range of 2.88 Å<a-axis<3.38 Å. The barrier layer 320 may comprise (1) fcc oxides, such as FeO, CoO, NiO, ZrO, MgO, TiO, MnO, and ZnO; (2) X—N or X—C composites (where X is Sc, Ti, V, Cr, Zr, Nb, Ta, Hf, or W), all of which with a-axis lattice parameters in the range of 4.08 Å to 4.75 Å; (3) alloy combination composites thereof with similar lattice parameter ranges; or (4) MO₂ tetragonal oxides (001) having an a-axis range 4.3 Å to 4.75 Å and c-axis range 2.9 Å to 3.2 Å. For example, the barrier layer 320 may comprise (1) B2 alloys of RuZr, RhZr, RuTa, or IrZr; (2) bcc alloys of TaW, WTi, CrMo; or (3) fcc oxides, X—N nitrides or X—C carbides mentioned above, with lattice materials in the range of 4.08 Å to 4.75 Å. The barrier layer 320 has a thickness in the y-direction of about 65 Å to about 150 Å, such as about 100 Å.

The laminated texture stack 302 of the buffer layer 310 comprises two or more alternating layers of RuAl and MgTiO or MgO, laminations of MgO and W or W—X bcc alloys, where X is one or more of Ta, Hf, Ti, V, Nb, and Mo, or any combination thereof. Each layer of RuAl and MgTiO or MgO may be laminated together when deposited. As shown, the laminated texture stack 302 comprises a first RuAl layer 306a disposed on the seed layer 304, a first MgTiO or MgO layer 308a disposed on the first RuAl layer 306a, a second RuAl layer 306b disposed on the first MgTiO or MgO layer 308a, a second MgTiO or MgO layer 308b disposed on the second RuAl layer 306b, and a third RuAl layer 306c disposed on the second MgTiO or MgO layer 308b. Each RuAl layer 306a-306c has a thickness in the y-direction of about 5 Å to about 15 Å, such as about 10 Å. Each MgTiO or MgO layer 308a, 308b has a thickness in the y-direction of about 25 Å to about 35 Å, such as about 30 Å. Thus, the laminated texture stack 302 has a total thickness in the y-direction of about 10 Å to about 70 Å. While three RuAl layers 306a-306c and two MgTiO or MgO layers 308a, 308b are shown, the laminated texture stack 302 may comprise any number of alternating RuAl and MgTiO or MgO layers. The stack 302 maybe also comprise laminated stacks of MgO and W, or W alloys like WTa, which are followed or pre-seeded by a texture layer, such as RuAl and IrAl.

Texture layers comprising RuAl only require a high temperature (e.g., about 300° C. or higher) to assist a strong (100) orientation growth. However, RuAl and MgTiO or MgO, W, and WX alloys have a tendency to grow in grains with (100) orientation at room temperature. By laminating the alternating layers of RuAl and MgTiO or MgO together, each layer 306a-306c, 308a, 308b of the laminated texture stack 302 grows progressively stronger (100) orientations at room temperature (e.g., about 25° C.). As such, the laminated texture stack 302 is able to provide a (100) orientation for the TI or TSM layer 312 without subjecting the SOT device 300 to high temperatures during formation. As such, the TI or TSM layer 312 is able to grow in a (100) or (012) orientation on the (100) orientation of the buffer layer 310, and the SOT device can be formed using, for example, ion beam deposition (IBD).

The FM layer 316 has a thickness of about 5 Å to about 15 Å, and may comprise NiFe, CoFe, NiFeX, CoFeX, FeX, or Nix, where X═Co, Ni, Cu, Si, Al, Mn, Ge, Ta, Hf, N, or B. The FM layer 316 may comprise any magnetic layer combination or alloy combination of these elements that can yield a low coercivity, negative magnetostrictive FM layer 316, or in multilayer combinations with other higher polarizing materials like Heusler alloys or high Ni containing alloy FM layers. The interlayer 314 may comprise MgO, CoFeB, Co, CoFe, NiFe, or a similar material as the FM layer 316.

The cap layer 318 may comprise non-magnetic, high resistivity materials, such as: thin ceramic oxides or nitrides of TiN, SiN, MgTiO, and MgO; amorphous/nanocrystalline metals such as NiFeGe, NiFeTa, NiTa, NiHf, NiFeHf, CoHf, CoFeHf, NiWTa, NiFeW, NiW, and WRe; or nitrides, oxides, or borides of above-mentioned elements, compounds, and/or alloys such as NiTaN, NiFeTaN, NiWTaN, NiWN, WREN, TaN, WN, TaOx, WOx, WB, HfB, NiHfB, NiFeHfB, CoHfB, and CoFeHfB, where x is a numeral. In some embodiments, lower atomic number (Z) materials are preferred in the cap layer 318 to reduce sputter intermixing with the FM layer 316, but high Z alloys can be used, if used in combination with a migration barrier beneath, or if the high Z elements are used with a high resistive oxide, nitride, or boride. The cap layer 318 can comprise multilayer combinations of the above-mentioned materials, and the overall thickness of the cap layer 318 is less than or equal to about 100 Å (nominally about 15 Å to about 50 Å).

The SOT device 350 of FIG. 3B is similar to the SOT device 300 of FIG. 3A; however, the buffer layer 360 comprises a laminated texture stack 352, a first barrier layer 354, an oxide layer 356, and a second barrier layer 358. In some embodiments, the second barrier layer 358 is a second texture layer 358. The laminated texture stack 352 is similar to the laminated texture stack 302 of the SOT device 300; however, the laminated texture stack 352 further comprises a third MgTiO or MgO layer 308c disposed on the third RuAl layer 306c, and a fourth RuAl layer 306d disposed on the third MgTiO or MgO layer 308c. Thus, the laminated texture stack 352 has a total thickness in the y-direction of about 15 Å to about 150 Å. While four RuAl layers 306a-306d and three MgTiO or MgO layers 308a-308c are shown, the laminated texture stack 352 may comprise any number of alternating RuAl and MgTiO or MgO layers, laminated layers of MgO and W, W—X alloys where X is mentioned above, or in combination with other texturing layers like RuAl.

The first barrier layer 354 is disposed on the fourth RuAl layer 306d, the oxide layer 356 is disposed on the first barrier layer 354, and the second barrier layer 358 is disposed on the oxide layer 356. The first barrier layer 354 may comprise any of the materials listed above for the barrier layer 320, and have a thickness in the y-direction of about 45 Å to about 55 Å, such as about 50 Å. The oxide layer 356 may comprise MgTiO or MgO and have a thickness in the y-direction of about 5 Å to about 50 Å, such as about 10 Å to about 30 Å. The second barrier layer 358 may comprise W and have a thickness in the y-direction of about 5 Å to about 10 Å, such as about 7 Å. The oxide layer 356 increases epitaxy and (012) growth, which enables the TI or TSM layer 312 comprising BiSb to have a stronger (012) orientation.

While the SOT devices 300, 350 illustrate the TI or TSM layer being disposed below the FM layer 316, the TI or TSM layer 312 may instead be disposed over the FM layer 316. Moreover, the interlayer 314 may comprise the same materials as the buffer layers 310 and 360, including the laminated texture stacks 302, 352, for example.

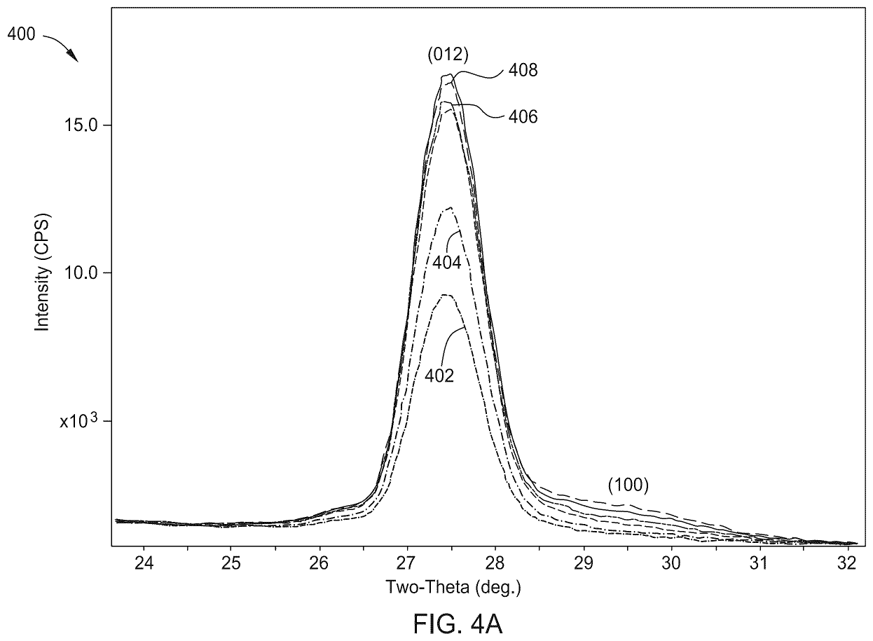

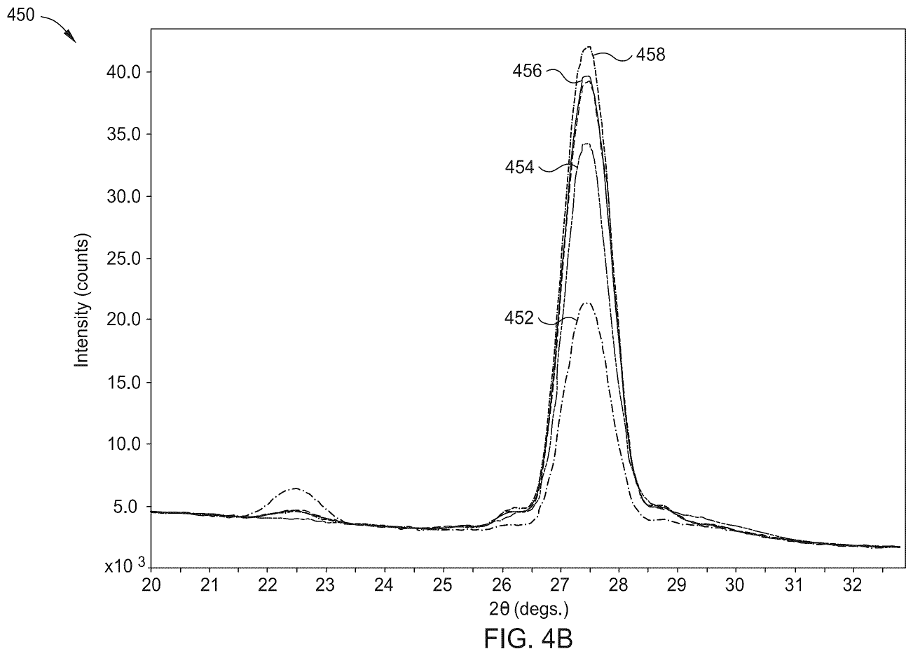

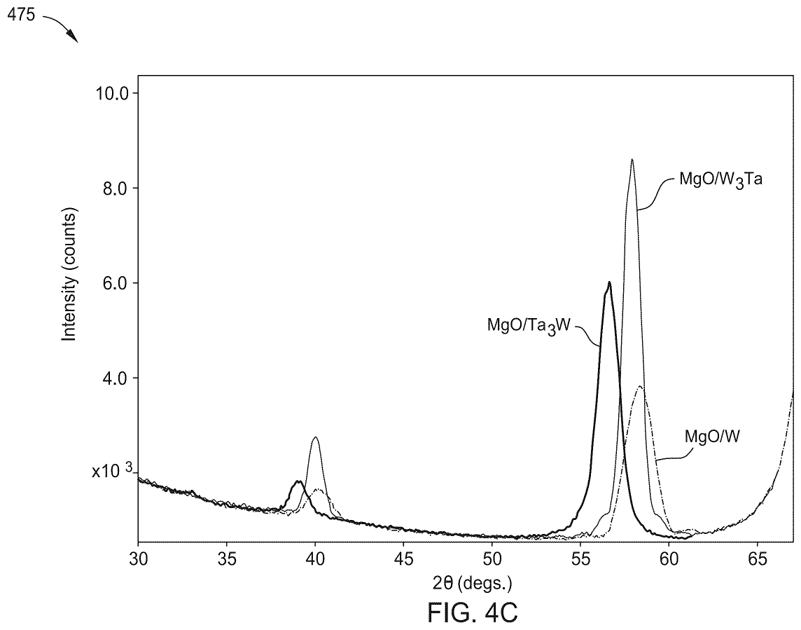

FIGS. 4A-4C illustrate various graphs 400, 450, 475, respectively, showing examples of buffer layers comprising laminated texture stacks of RuAl and MgTiO or MgO, according to various embodiments. The laminated texture stacks represented may be the laminated texture stack 302 of FIG. 3A or the laminated texture stack 352 of FIG. 3B.

The graph 400 of FIG. 4A illustrates the (012) growth of laminated texture stacks comprising different numbers of alternating RuAl and MgTiO or MgO layers, according to one embodiment. Line 402 represents a laminated texture stack comprising one RuAl layer and one MgTiO or MgO layer disposed thereon. Line 404 represents a laminated texture stack comprising one MgTiO or MgO layer and one RuAl layer disposed thereon. Line 406 represents a laminated texture stack comprising two or more RuAl layers disposed and two MgTiO or MgO layer disposed thereon. Line 408 represents a laminated texture stack comprising three or more RuAl layers disposed and three MgTiO or MgO layer disposed thereon. As shown by the graph 400, the tri-layer laminated stack represented by line 408 produces the stronger (100) texture, followed by the dual-layer laminated stack represented by line 406. Thus, more RuAl and MgTiO or MgO layers within a laminated stack results in a stronger (100) orientation for the buffer layer.

The graph 450 of FIG. 4B illustrates the (100) growth of various buffer layers comprising laminated texture stacks, according to another embodiment. In the graph 450, each SOT device represented by lines 452-458 comprises a seed layer comprising NiTa, NiFeTa, CoFeTa, or NiFeGe, a laminated stack of RuAl and MgTiO, a TI or TSM layer comprising BiSb, an interlayer comprising NiFeGe, a FM layer comprising CoFe, and a cap layer comprising NiFeGe.

However, the laminated stack of each SOT device represented by lines 452-458 varies. Line 452 represents a SOT device comprising a dual laminated layer of RuAl and MgTiO or MgO, line 454 represents a SOT device comprising a laminated tri-layer of RuAl and MgTiO or MgO, line 456 represents a SOT device comprising a dual laminated layer of RuAl and MgTiO or MgO and a laminated texture layer disposed on the laminated dual layer comprising five layers of W and MgTiO, and line 458 represents a SOT device comprising a dual layer of RuAl and MgTiO or MgO, a barrier layer disposed on the dual layer comprising W, and an oxide layer disposed on the barrier layer comprising MgTiO. As shown in the graph, lines 456 and 458 achieve the strongest (100) texture. Thus, more RuAl and MgTiO or MgO layers within a laminated stack results in a stronger (100) orientation for the buffer layer, and a SOT device comprising an oxide layer results in a stronger (100) orientation for the buffer layer.

Furthermore, FIG. 4C shows laminates of MgO/W, MgO/Ta₃W, and MgO/W₃Ta alloys can grow a (100) TaW layer, and can be used at room temperature with RuAl to make stronger (100) textured stacks. The peaks showing (100) texture with MgO/WTa laminate are around 56 degrees.

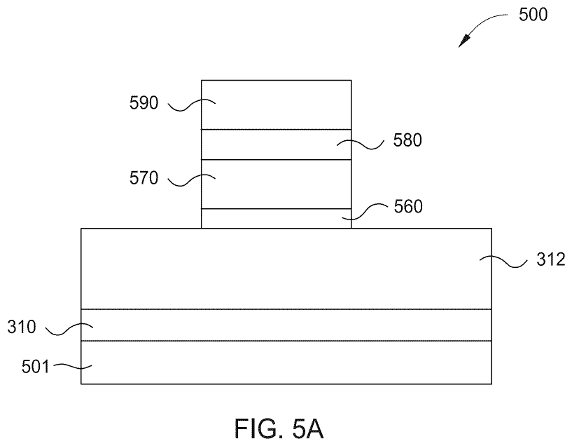

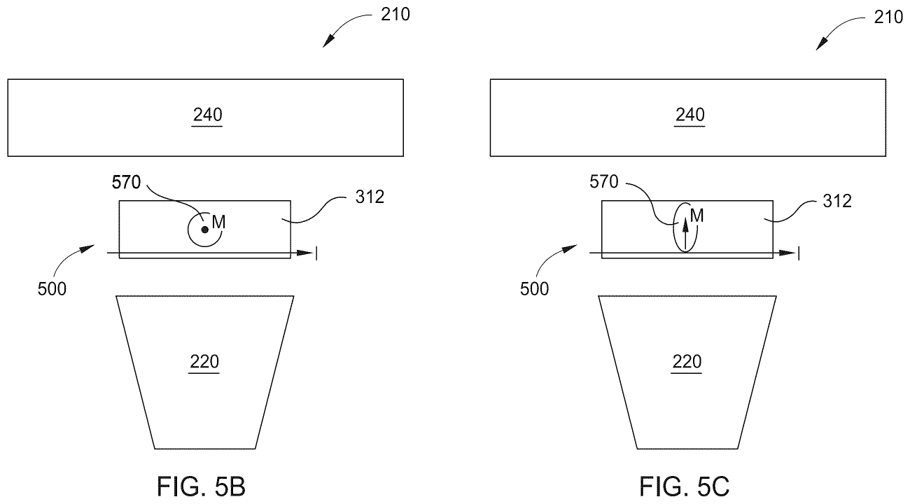

FIG. 5A is a schematic cross-sectional view of a SOT device 500 for use in a MAMR magnetic recording head, such as the MAMR magnetic recording head of the drive 100 of FIG. 1 or other suitable magnetic media drives. The SOT device 500 comprises a TI or TSM layer 312 orientation formed over a buffer layer 310 formed over a substrate 501, such as the TI or TSM layer 312 and the buffer layer 310 of FIG. 3A or the TI or TSM layer 312 and the buffer layer 360 of FIG. 3B. Thus, the TI or TSM layer 312 may comprise YPtBi having a (100) orientation, YPtBi having a (110) orientation, or BiSb having a (012) orientation. A spin torque layer (STL) 570 is formed over the TI or TSM layer 312. The STL 570 comprises a ferromagnetic material such as one or more layers of CoFe, CoIr, NiFe, and CoFeX alloy wherein X═B, Ta, Re, or Ir.

In certain embodiments, an electrical current shunt blocking layer 560 is disposed between the TI or TSM layer 312 and the STL 570. The electrical current shunt blocking layer 560 reduces electrical current from flowing from the TI or TSM layer 312 to the STL 570 but allows spin orbital coupling of the TI or TSM layer 312 and the STL 570. In certain embodiments, the electrical current shunt blocking layer 560 comprises a magnetic material which provides greater spin orbital coupling between the TI or TSM layer 312 and the STL 570 than a non-magnetic material. In certain embodiments, the electrical current shunt blocking layer 560 comprises a magnetic material of FeCo, FeCoM, FeCoMO, FeCoMMeO, FeCoM/MeO stack, FeCoMNiMnMgZnFeO, FeCoM/NiMnMgZnFeO stack, multiple layers/stacks thereof, or combinations thereof in which M is one or more of B, Si, P, Al, Hf, Zr, Nb, Ti, Ta, Mo, Mg, Y, Cu, Cr, and Ni, and Me is Si, Al, Hf, Zr, Nb, Ti, Ta, Mg, Y, or Cr. In certain embodiments, the electrical current shunt blocking layer 560 is formed to a thickness from about 10 Å to about 100 Å. In certain aspects, an electrical current shunt blocking layer 560 having a thickness of over 100 Å may reduce spin orbital coupling of the TI or TSM layer 312 and the STL 570. In certain aspects, an electrical current shunt blocking layer having a thickness of less than 10 Å may not sufficiently reduce electrical current from TI or TSM layer 312 to the STL 570.

In certain embodiments, additional layers are formed over the STL 570 such as a spacer layer 580 and a pinning layer 590. The pinning layer 590 can partially pin the STL 570. The pinning layer 590 comprises a single or multiple layers of PtMn, NiMn, IrMn, IrMnCr, CrMnPt, FeMn, other antiferromagnetic materials, or combinations thereof. The spacer layer 580 comprises single or multiple layers of magnesium oxide, aluminum oxide, other non-magnetic materials, or combinations thereof.

FIGS. 5B-5C are schematic MFS views of certain embodiments of a portion of a MAMR magnetic recording head 210 with a SOT device 500 of FIG. 5A. The MAMR magnetic recording head 210 can be the write head FIG. 2 or other suitable magnetic recording heads in the drive 100 of FIG. 1 or other suitable magnetic media drives such as tape drives. The MAMR magnetic recording head 210 includes a main pole 220 and a trailing shield 240 in a track direction. The SOT device 500 is disposed in a gap between the main pole and the trailing shield 240.

During operation, charge current through a TI or TSM layer or layer stack 312 acting as a spin Hall layer generates a spin current in the TI or TSM layer. The spin orbital coupling of the TI or TSM layer and a spin torque layer (STL) 570 causes switching or precession of magnetization of the STL 570 by the spin orbital coupling of the spin current from the TI or TSM layer 312. Switching or precession of the magnetization of the STL 570 can generate an assisting AC field to the write field. Energy assisted magnetic recording heads based on SOT have multiple times greater power efficiency in comparison to MAMR magnetic recording heads based on spin transfer torque. As shown in FIG. 5B, an easy axis of a magnetization direction of the STL 570 is perpendicular to the MFS from shape anisotropy of the STL 570, from the pinning layer 590 of FIG. 5A, and/or from hard bias elements proximate the STL 570. As shown in FIG. 5C, an easy axis of a magnetization direction of the STL 570 is parallel to the MFS from shape anisotropy of the STL 570, from the pinning layer 590 of FIG. 5A, and/or from hard bias elements proximate the STL 570.

FIGS. 6 and 7 show a top SOT MRAM device and a bottom SOT MRAM device respectively, according to various embodiments.

FIG. 6 is a schematic cross-sectional view of a magnetic tunnel junction (MTJ) 601 used as a top SOT MRAM device 600, according to one embodiment. The MRAM device 600 comprises an MTJ 601, which includes a ferromagnetic (FM) reference layer (RL) 610, a spacer or barrier layer 620 over the RL 610, and an FM recording layer 630 over the spacer or barrier layer 620. In addition, the MRAM device 600 comprises an interlayer 314 over an electrical current shunt blocking layer 640 over the recording layer 630 of the MTJ 601, and a TI or TSM layer 312 over the interlayer 314. The interlayer provides a means to transfer the material structure symmetry from the underlying layers of the MTJ to the TI or TSM layer. This is in contrast to the buffer layer used in FIG. 7, which is necessary to set the material structure and grow the TI or TSM layer in the bottom SOT configuration.

The TI or TSM layer 312 and the interlayer 314 may be the TI or TSM layer 312 and the interlayer 314 of FIG. 3A or the TI or TSM layer 332 and the buffer layer 360 of FIG. 3B. Thus, the TI or TSM layer 312 may comprise YPtBi having a (100) orientation, YPtBi having a (110) orientation, or BiSb having a (012) orientation. The interlayer 314 corresponds to that in FIGS. 3A-3B, and may comprise, in addition to the material options described above, the options of MgO and NiFeGe (e.g., layer may comprise MgO or NiFeGe). It may also include the material options for the buffer layer as noted above. In addition, the FM recording layer 630 corresponds to the FM layer 316 in FIGS. 3A-3B, except that, unlike in FIGS. 3A and 3B, this top SOT configuration in FIG. 6 has the TI or TSM layer and interlayer disposed over the FM layer 316 (FM recording layer 630). Other layers such as the seed or cap layer in FIGS. 3A-3B above may be optionally included here but not shown.

The RL 610 comprises single or multiple layers of CoFe, other ferromagnetic materials, and combinations thereof. The spacer or barrier layer 620 comprises single or multiple layers of magnesium oxide (MgO), aluminum oxide, other dielectric materials, or combinations thereof. The recording layer 630 comprises single or multiple layers of CoFe, NiFe, other ferromagnetic materials, or combinations thereof, or may comprise material options noted above for the FM layer 316.

As noted above, in certain embodiments, the electrical current shunt blocking layer 640 is disposed between the interlayer 314 and the recording layer 630. The electrical current shunt blocking layer 640 reduces electrical current from flowing from the TI or TSM layer 312 to the recording layer 630 but allows spin orbital coupling of the TI or TSM layer 312 and the recording layer 630. For example, writing to the MRAM device can be enabled by the spin orbital coupling of the TI or TSM layer 312 and the recording layer 630, which enables switching of magnetization of the recording layer 630 by the spin orbital coupling of the spin current from the TI or TSM layer 312. In certain embodiments, the electrical current shunt blocking layer 640 comprises a magnetic material which provides greater spin orbital coupling between the TI or TSM layer 312 and the recording layer 630 than a non-magnetic material. In certain embodiments, the electrical current shunt blocking layer 640 comprises a magnetic material of FeCoM, FeCoMO, FeCoMMeO, FeCoM/MeO stack, FeCoMNiMnMgZnFeO, FeCoM/NiMnMgZnFeO stack, multiple layers/stacks thereof, or combinations thereof, in which M is one or more of B, Si, P, AI, Hf, Zr, Nb, Ti, Ta, Mo, Mg, Y, Cu, Cr, and Ni, and Me is Si, Al, Hf, Zr, Nb, Ti, Ta, Mg, Y, or Cr.

The MRAM device 600 of FIG. 6 may include other layers, such as pinning layers, pinning structures (e.g., a synthetic antiferromagnetic (SAF) pinned structure), electrodes, gates, and other structures. It is noted that, in other embodiments, the MRAM device may include the TI or TSM layer 312 at the bottom of the stack.

FIG. 7 is a schematic cross-sectional view of another MRAM device 700 according to one embodiment, which has a bottom SOT stack configuration, with a TI or TSM bottom layer below the MTJ, in contrast to the top SOT stack configuration of FIG. 6.

As illustrated in FIG. 7, the MRAM device 700 includes a buffer layer 310, a TI or TSM layer or layer 312 over the buffer layer 310, an interlayer 314 over the TI or TSM layer 312, an electrical current shunt blocking layer 640 over the interlayer 314, and an MTJ 701 over the electrical current shunt blocking layer 640. The MTJ 701 includes an FM recording layer 730, a spacer or barrier layer 720 over the FM recording layer 730, and an FM reference layer (RL) 710 over the spacer or barrier layer 720.

The TI or TSM layer 312 and the buffer layer 310 may be the TI or TSM layer 312 and the buffer layer 310 of FIG. 3A or the TI or TSM layer 332 and the buffer layer 360 of FIG. 3B. Thus, the TI or TSM layer 312 may comprise YPtBi having a (100) orientation, YPtBi having a (110) orientation, or BiSb having a (012) orientation. The interlayer 314 corresponds to that in FIGS. 3A-3B, and may comprise, in addition to the material options described above, the options of MgO and NiFeGe (e.g., layer may comprise MgO or NiFeGe). The interlayer 314 may also include the material options for the buffer layer as noted above. In addition, the recording layer 730 corresponds to the FM layer 316 in FIGS. 3A-3B. The layers of the MTJ and the electrical current shunt blocking layer of FIG. 7 otherwise correspond to those of FIG. 6 and may comprise the above described material options. Other layers such as the seed or cap layer in FIGS. 3A-3B above may be optionally included here but not shown. Like in FIG. 6, the MRAM device 700 of FIG. 7 may include other layers, such as pinning layers, pinning structures (e.g., a synthetic antiferromagnetic (SAF) pinned structure), electrodes, gates, and other structures.

Generally speaking, in either of the MRAM device 600 or 700, the TI or TSM layer 312 serves as a spin injection source to write data in the MRAM device, whereby a current flowing in a plane of the TI or TSM layer causes a spin current in a direction perpendicular to the plane. Then, the spin current causes switching of the magnetic orientation of the recording layer 630 or 730, reflecting storage of a data bit. The magnetic orientation of the recording layer 630 or 730 relative to that of the reference layer 610 or 710 determines the resistance of the MTJ 601 or 701, enabling the read out of that stored data bit value. The MRAM device 600 or 700 may be implemented as a two or three terminal device. In certain embodiments, the MRAM device 600 or 700 may be configured as part of a neuromorphic array, through which individual MRAM devices are configured to store weights for machine learning computational purposes (e.g., multiply-accumulate operations). An example of such an array is disclosed in co-pending application titled “Matrix-Vector Multiplication Using SOT-based Non-Volatile Memory Cells,” U.S. application Ser. No. 17/172,155, filed Feb. 10, 2021, the disclosure of which is hereby incorporated by reference.

In other embodiments, the material stack configurations of FIGS. 6 and 7 may be part of a spin Hall oscillator instead of an MRAM device, where the recording layer 610 or 710 becomes instead a spin oscillator layer. It is caused to process by the spin current from the TI or TSM layer 312. A controlled current source into the TI or TSM layer enables control of the oscillation from the spin Hall oscillator device. The mechanism is similar to the MAMR recording head embodiment of FIGS. 5A-5C described above.

In other embodiments, the SOT device of FIGS. 3A-3B are embodied in other applicable spin-to-charge or charge-to-spin conversion use cases. As an example, they can be used in machine learning applications such as those disclosed in co-pending application titled “Spin Orbital Squared (SO-SO) Logic,” U.S. application Ser. No. 18/645, 189, filed Apr. 24, 2024, co-pending application titled “Deep Neural Network Device Based on Dual Spin Orbit Torque (SOT) Devices,” U.S. application Ser. No. 18/645,195, filed Apr. 24, 2024, and co-pending application titled “In-Memory Deep Neural Network Device Using Spin Orbit Torque (SOT) With Multi-State Weight,” U.S. application Ser. No. 18/954,415, filed Nov. 20, 2024, the disclosures of which are hereby incorporated by reference. As another example, they can be used in magnetic sensing applications such as those disclosed in co-pending application titled “Magnetic Sensor Half-Bridge Based on Inverse Spin Hall Effect with Reduced Thermal Drift,” U.S. application Ser. No. 18/545,847, filed Dec. 19, 2023, and co-pending application titled “Sensor based on Direct Spin Hall Effect,” U.S. application Ser. No. 18/666,543, filed May 16, 2024, the disclosures of which are hereby incorporated by reference.

Therefore, by laminating alternating layers of RuAl and MgTiO or MgO together in a buffer layer, each layer of the laminated texture stack grows progressively stronger (100) orientations at room temperature (e.g., about 25° C.). As such, the laminated texture stack is able to provide a (100) orientation for the TI or TSM layer without subjecting the SOT device to high temperatures during formation. As such, the TI or TSM layer is able to grow in a (100) or (012) orientation on the (100) orientation of the buffer layer, and the SOT device can be formed using, for example, ion beam deposition (IBD).

In one embodiment, a spin-orbit torque (SOT) device comprises a texture layer structure having a (100) orientation comprising one or more of: (1) two or more laminated layers of RuAl and MgTiO or MgO, (2) laminations of MgO and W, or (3) W-X body-centered cubic (bcc) alloys, where X is one or more of Ta, Hf, Ti, V, Nb, and Mo, the texture layer structure having a (100) orientation, and a topological insulator (TI) or a topological semi-metal (TSM) layer disposed over the texture layer structure.

The TI or TSM layer comprises BiSb having a (012) orientation. The texture layer structure comprises two or more laminated layers of RuAl and MgTiO or MgO. The SOT device further comprises an interlayer and a ferromagnetic layer. The texture layer structure comprises two or more laminated layers of RuAl and MgTiO or MgO, the RuAl of each laminated layer has a thickness of about 25 Å to about 35 Å, and the MgTiO or MgO of each laminated layer has a thickness of about 5 Å to about 15 Å. The SOT device further comprises a barrier layer disposed between the texture layer structure and the TI or TSM layer, and an oxide layer disposed between the barrier layer and the TI or TSM layer. The texture layer structure comprises the laminations of MgO and W. The texture layer structure comprises the W-X body-centered cubic (bcc) alloys, where X is one or more of Ta, Hf, Ti, V, Nb, and Mo. The texture layer structure comprises the two or more laminated layers of RuAl and MgTiO or MgO. A magnetic recording head comprises the SOT device. A magnetic recording device comprises the magnetic recording head. A magneto-resistive memory comprises the SOT device.

In another embodiment, a spin-orbit torque (SOT) device comprises a seed layer comprising an amorphous material, a texture layer structure disposed on the seed layer, the texture layer structure having a (100) orientation comprising one or more of: (1) two or more laminated layers of RuAl and MgTiO or MgO, (2) laminations of MgO and W, or (3) W-X body-centered cubic (bcc) alloys, where X is one or more of Ta, Hf, Ti, V, Nb, and Mo, wherein the RuAl of each laminated layer has a greater thickness than the MgTiO or MgO of each laminated layer, a topological insulator (TI) or a topological semi-metal (TSM) layer disposed over the texture layer structure, an interlayer disposed on the TI or TSM layer, and a ferromagnetic layer disposed on the interlayer.

The texture layer structure has a thickness of about 10 Å to about 150 Å. The two or more laminated layers of RuAl and MgTiO or MgO comprises: a first RuAl layer disposed on the seed layer, a first MgTiO or MgO layer disposed on the first RuAl layer, a second RuAl layer disposed on the first MgTiO or MgO layer, a second MgTiO or MgO layer disposed on the second RuAl layer, and a third RuAl layer disposed on the second MgTiO or MgO layer. The TI or TSM layer comprises BiSb having a (012) orientation or YPtBi having a (100) orientation. The texture layer structure comprises two or more laminated layers of RuAl and MgTiO or MgO, and the RuAl of each laminated layer has a greater thickness than the MgTiO or MgO of each laminated layer. The texture layer structure comprises the laminations of MgO and W. The texture layer structure comprises the W-X body-centered cubic (bcc) alloys, where X is one or more of Ta, Hf, Ti, V, Nb, and Mo. The two or more laminated layers of RuAl and MgTiO or MgO comprises: a first RuAl layer disposed on the seed layer, a first MgTiO or MgO layer disposed on the first RuAl layer, a second RuAl layer disposed on the first MgTiO or MgO layer, a second MgTiO or MgO layer disposed on the second RuAl layer, a third RuAl layer disposed on the second MgTiO or MgO layer, a third MgTiO or MgO layer disposed on the third RuAl layer, and a fourth RuAl layer disposed on the third MgTiO or MgO layer. A magnetic recording head comprises the SOT device. A magnetic recording device comprises the magnetic recording head. A magneto-resistive memory comprises the SOT device.

In yet another embodiment, a spin-orbit torque (SOT) device comprises a buffer layer comprising: a texture layer disposed on a seed layer, the texture layer structure having a (100) orientation comprising one or more of: (1) two or more laminated layers of RuAl and MgTiO or MgO, (2) laminations of MgO and W, or (3) W-X body-centered cubic (bcc) alloys, where X is one or more of Ta, Hf, Ti, V, Nb, and Mo, a first barrier layer disposed on the texture layer structure, and an oxide layer disposed on the first barrier layer, a topological insulator (TI) or a topological semi-metal (TSM) layer disposed over the texture layer structure, an interlayer disposed on the TI or TSM layer, and a ferromagnetic layer disposed on the interlayer.

The first barrier layer comprises W, and the oxide layer comprises MgTiO. The first barrier layer has a thickness of about 40 Å to about 60 Å, and wherein the oxide layer has a thickness of about 5 Å to about 50 Å. The texture layer structure comprises two or more laminated layers of RuAl and MgTiO or MgO, and the RuAl of each laminated layer has a greater thickness than the MgTiO or MgO of each laminated layer. The TI or TSM layer comprises BiSb having a (012) orientation or YPtBi having a (100) orientation. The SOT device further comprises a second barrier layer disposed between the oxide layer and the TI or TSM layer. The texture layer structure comprises the laminations of MgO and W. The texture layer structure comprises the W-X body-centered cubic (bcc) alloys, where X is one or more of Ta, Hf, Ti, V, Nb, and Mo. The texture layer structure comprises the two or more laminated layers of RuAl and MgTiO or MgO. A magnetic recording head comprises the SOT device. A magnetic recording device comprises the magnetic recording head. A magneto-resistive memory comprises the SOT device.

While the foregoing is directed to embodiments of the present disclosure, other and further embodiments of the disclosure may be devised without departing from the basic scope thereof, and the scope thereof is determined by the claims that follow.

What is claimed is:

1. A spin-orbit torque (SOT) device, comprising:
a texture layer structure having a (100) orientation, the texture layer structure comprising one of more of:
(1) two or more laminated layers of RuAl and MgTiO or MgO;
(2) laminations of MgO and W; or
(3) W-X body-centered cubic (bcc) alloys, where X is one or more of Ta, Hf, Ti, V, Nb, and Mo; and
a topological insulator (TI) or a topological semi-metal (TSM) layer disposed over the texture layer structure.

2. The SOT device of claim 1, wherein the TI or TSM layer comprises BiSb having a (012) orientation.

3. The SOT device of claim 1, wherein the texture layer structure comprises the two or more laminated layers of RuAl and MgTiO or MgO.

4. The SOT device of claim 1, further comprising:
an interlayer; and
a ferromagnetic layer.

5. The SOT device of claim 1, wherein the texture layer structure comprises the two or more laminated layers of RuAl and MgTiO or MgO, wherein the RuAl of each laminated layer has a thickness of about 25 Å to about 35 Å, and wherein the MgTiO or MgO of each laminated layer has a thickness of about 5 Å to about 15 Å.

6. The SOT device of claim 1, further comprising:
a barrier layer disposed between the texture layer structure and the TI or TSM layer; and
an oxide layer disposed between the barrier layer and the TI or TSM layer.

7. The SOT device of claim 1, wherein the texture layer structure comprises the laminations of MgO and W.

8. The SOT device of claim 1, wherein the texture layer structure comprises the W-X body-centered cubic (bcc) alloys, where X is one or more of Ta, Hf, Ti, V, Nb, and Mo.

9. A magnetic recording head comprising the SOT device of claim 1.

10. A magnetic recording device comprising the magnetic recording head of claim 9.

11. A magneto-resistive memory comprising the SOT device of claim 1.

12. A spin-orbit torque (SOT) device, comprising:
a seed layer comprising an amorphous material;
a texture layer structure having a (100) orientation disposed on the seed layer, the texture layer structure comprising one or more of:
(1) two or more laminated layers of RuAl and MgTiO or MgO;
(2) laminations of MgO and W; or
(3) W-X body-centered cubic (bcc) alloys, where X is one or more of Ta, Hf, Ti, V, Nb, and Mo;
a topological insulator (TI) or a topological semi-metal (TSM) layer disposed over the texture layer structure;
an interlayer disposed on the TI or TSM layer; and
a ferromagnetic layer disposed on the interlayer.

13. The SOT device of claim 12, wherein the texture layer structure has a thickness of about 10 Å to about 150 Å.

14. The SOT device of claim 12, wherein the two or more laminated layers of RuAl and MgTiO or MgO comprises:
a first RuAl layer disposed on the seed layer;
a first MgTiO or MgO layer disposed on the first RuAl layer;
a second RuAl layer disposed on the first MgTiO or MgO layer;
a second MgTiO or MgO layer disposed on the second RuAl layer; and
a third RuAl layer disposed on the second MgTiO or MgO layer.

15. The SOT device of claim 12, wherein the TI or TSM layer comprises BiSb having a (012) orientation or YPtBi having a (100) orientation.

16. The SOT device of claim 12, wherein the texture layer structure comprises two or more laminated layers of RuAl and MgTiO or MgO, and wherein the RuAl of each laminated layer has a greater thickness than the MgTiO or MgO of each laminated layer.

17. The SOT device of claim 12, wherein the texture layer structure comprises the laminations of MgO and W.

18. The SOT device of claim 12, wherein the texture layer structure comprises the W-X body-centered cubic (bcc) alloys, where X is one or more of Ta, Hf, Ti, V, Nb, and Mo.

19. The SOT device of claim 12, wherein the two or more laminated layers of RuAl and MgTiO or MgO comprises:
a first RuAl layer disposed on the seed layer;
a first MgTiO or MgO layer disposed on the first RuAl layer;
a second RuAl layer disposed on the first MgTiO or MgO layer;
a second MgTiO or MgO layer disposed on the second RuAl layer;
a third RuAl layer disposed on the second MgTiO or MgO layer;
a third MgTiO or MgO layer disposed on the third RuAl layer; and
a fourth RuAl layer disposed on the third MgTiO or MgO layer.

20. A magnetic recording head comprising the SOT device of claim 12.

21. A magnetic recording device comprising the magnetic recording head of claim 20.

22. A magneto-resistive memory comprising the SOT device of claim 12.

23. A spin-orbit torque (SOT) device, comprising:
a buffer layer comprising:
a texture layer structure having a (100) orientation disposed on a seed layer, the texture layer structure comprising one or more of:
(1) two or more laminated layers of RuAl and MgTiO or MgO;
(2) laminations of MgO and W;
(3) W-X body-centered cubic (bcc) alloys, where X is one or more of Ta, Hf, Ti, V, Nb, and Mo;
a first barrier layer disposed on the texture layer structure; and
an oxide layer disposed on the first barrier layer;
a topological insulator (TI) or a topological semi-metal (TSM) layer disposed over the texture layer structure;
an interlayer disposed on the TI or TSM layer; and
a ferromagnetic layer disposed on the interlayer.

24. The SOT device of claim 23, wherein the first barrier layer comprises W, and wherein the oxide layer comprises MgTiO.

25. The SOT device of claim 24 wherein the first barrier layer has a thickness of about 40 Å to about 60 Å, and wherein the oxide layer has a thickness of about 5 Å to about 50 Å.

26. The SOT device of claim 23, wherein the texture layer structure comprises two or more laminated layers of RuAl and MgTiO or MgO, and wherein the RuAl of each laminated layer has a greater thickness than the MgTiO or MgO of each laminated layer.

27. The SOT device of claim 23, wherein the TI or TSM layer comprises BiSb having a (012) orientation or YPtBi having a (100) orientation.

28. The SOT device of claim 23, further comprising a second barrier layer disposed between the oxide layer and the TI or TSM layer.

29. The SOT device of claim 23, wherein the texture layer structure comprises the laminations of MgO and W.

30. The SOT device of claim 23, wherein the texture layer structure comprises the W-X body-centered cubic (bcc) alloys, where X is one or more of Ta, Hf, Ti, V, Nb, and Mo.

31. The SOT device of claim 23, wherein the texture layer structure comprises the two or more laminated layers of RuAl and MgTiO or MgO.

32. A magnetic recording head comprising the SOT device of claim 23.

33. A magnetic recording device comprising the magnetic recording head of claim 32.

34. A magneto-resistive memory comprising the SOT device of claim 23.
